(19) United States
(12) Patent Application Publication
(10) Pub. No.: US 2023/0343706 A1
(43) Pub. Date: Oct. 26, 2023

(54) SEMICONDUCTOR DEVICE AND METHOD OF FABRICATING THE SAME

(71) Applicant: Samsung Electronics Co., Ltd., Suwon-si (KR)

(72) Inventors: Hauk HAN, Suwon-si (KR); Seonghun PARK, Suwon-si (KR); Jeonggil LEE, Suwon-si (KR)

(73) Assignee: Samsung Electronics Co., Ltd., Suwon-si (KR)

(21) Appl. No.: 18/158,692

(22) Filed: Jan. 24, 2023

(30) Foreign Application Priority Data
Apr. 20, 2022 (KR) 10-2022-0049048

(51) Int. Cl. H01L 23/528; H01L 23/532

(52) U.S. Cl. CPC H01L 23/5283; H01L 23/53266

(57) ABSTRACT

A semiconductor device includes an insulating structure, a first conductive structure in the insulating structure, the first conductive structure including a first conductive layer and a second conductive layer, and a second conductive structure in the insulating structure, the second conductive structure including a first conductive layer of the second conductive structure. A width of the first conductive structure is larger than a width of the second conductive structure. The first conductive layer of the first conductive structure, the second conductive layer of the first conductive structure, and the first conductive layer of the second conductive structure include a same nonmetal element. A concentration of the nonmetal element in the second conductive layer of the first conductive structure is higher than a concentration of the nonmetal element in the first conductive layer of the first conductive structure and first conductive layer of the second conductive structure.

### CROSS-REFERENCE TO RELATED APPLICATION

This U.S. non-provisional patent application claims priority under 35 U.S.C. § 119 to Korean Patent Application No. 10-2022-0049048, filed on Apr. 20, 2022, in the Korean Intellectual Property Office, the entire contents of which are hereby incorporated by reference.

### FIELD

Some of the example embodiments relate to a semiconductor device and/or a method of fabricating the same, including a semiconductor device including a conductive structure and/or a method of fabricating the same.

### BACKGROUND

Due to their small-sized, multifunctional, and/or low-cost characteristics, semiconductor devices are being esteemed as important elements in the electronics industry. The semiconductor devices are classified into a semiconductor memory device for storing data, a semiconductor logic device for processing data, and a hybrid semiconductor device including both of memory and logic elements.

With the recent trend of high speed and low power consumption of electronic devices, semiconductor devices in the electronic devices are also desired or required to have high operating speeds and/or low operating voltages, and in order to satisfy this goal or requirement, it is desired or necessary to increase an integration density of the semiconductor device. However, as the integration density of the semiconductor device increases, the semiconductor device may suffer from deterioration in electrical characteristics and production yield. Accordingly, many studies are being conducted to improve the electrical characteristics and production yield of the semiconductor device.

### SUMMARY

An example embodiment of the inventive concepts provides a semiconductor device with improved electrical and reliability characteristics and/or a method of fabricating the same.

According to an example embodiment of the inventive concepts, a semiconductor device includes an insulating structure, a first conductive structure in the insulating structure, the first conductive structure including a first conductive layer and a second conductive layer, wherein the second conductive layer is in the first conductive layer, and a second conductive structure in the insulating structure, the second conductive structure including a first conductive layer of the second conductive structure. A width of the first conductive structure is larger than a width of the second conductive structure. The first conductive layer of the first conductive structure, the second conductive layer of the first conductive structure, and the first conductive layer of the second conductive structure include a same nonmetal element. A concentration of the nonmetal element in the second conductive layer of the first conductive structure is higher than a concentration of the nonmetal element in the first conductive layer of the first conductive structure, and the concentration of the nonmetal element in the second conductive layer of the first conductive structure is higher than a concentration of the nonmetal element in the first conductive layer of the second conductive structure.

According to an example embodiment of the inventive concepts, a semiconductor device includes an insulating structure, a first conductive structure in the insulating structure, the first conductive structure including a first conductive layer and a second conductive layer, wherein the second conductive layer is in the first conductive layer, and a second conductive structure in the insulating structure. The second conductive structure includes a first conductive layer of the second conductive structure. A width of the first conductive structure is larger than a width of the second conductive structure, a mean size of grains in the second conductive layer of the first conductive structure is larger than a mean size of grains in the first conductive layer of the first conductive structure, and the mean size of grains in the second conductive layer of the first conductive structure is larger than a mean size of grains in the first conductive layer of the second conductive structure.

According to an example embodiment of the inventive concepts, a semiconductor device including an insulating structure, a first conductive structure in the insulating structure, the first conductive structure including a first conductive layer and a second conductive layer, wherein the second conductive layer is in the first conductive layer, and a second conductive structure in the insulating structure, the second conductive structure including a conductive layer. A width of the first conductive structure is larger than a width of the second conductive structure, and the first conductive structure is at a same level as the second conductive structure. The first conductive layer of the first conductive structure, the second conductive layer of the first conductive structure, and the conductive layer of the second conductive structure include a same nonmetal element. A concentration of the nonmetal element in the second conductive layer of the first conductive structure is higher than a concentration of the nonmetal element in the first conductive layer of the first conductive structure, the concentration of the nonmetal element in the second conductive layer of the first conductive structure is higher than a concentration of the nonmetal element in the conductive layer of the second conductive structure, and the nonmetal element is one of F, Cl, Br, C, O, or H.

According to an example embodiment of the inventive concepts, a method of fabricating a semiconductor device, including forming a first opening and a second opening in an insulating structure, wherein a width of the first opening is larger than a width of the second opening, forming a first preliminary conductive layer using an atomic layer deposition (ALD) process, wherein the first preliminary conductive layer partially fills the first opening and completely fills the second opening, forming a second preliminary conductive layer using a chemical vapor deposition (CVD) process, wherein the second preliminary conductive layer completely fills the first opening, and removing an upper portion of the first preliminary conductive layer and an upper portion of the second preliminary conductive layer to form a first conductive structure and a second conductive structure.

### BRIEF DESCRIPTION OF THE DRAWINGS

FIG. 1 is a sectional view illustrating a semiconductor device according to an example embodiment of the inventive concepts.

FIGS. 2A, 2B, 2C, and 2D are sectional views illustrating a method of fabricating the semiconductor device of FIG. 1.

FIG. 3 is a sectional view illustrating a semiconductor device according to an example embodiment of the inventive concepts.

FIGS. 4A and 4B are sectional views illustrating a method of fabricating the semiconductor device of FIG. 3.

FIG. 5 is a sectional view illustrating a semiconductor device according to an example embodiment of the inventive concepts.

FIG. 6 is a sectional view illustrating a semiconductor device according to an example embodiment of the inventive concepts.

FIG. 7 is a sectional view illustrating a semiconductor device according to an example embodiment of the inventive concepts.

FIG. 8 is a sectional view illustrating a semiconductor device according to an example embodiment of the inventive concepts.

### DETAILED DESCRIPTION

Example embodiments of the inventive concepts will now be described more fully with reference to the accompanying drawings, in which example embodiments are shown.

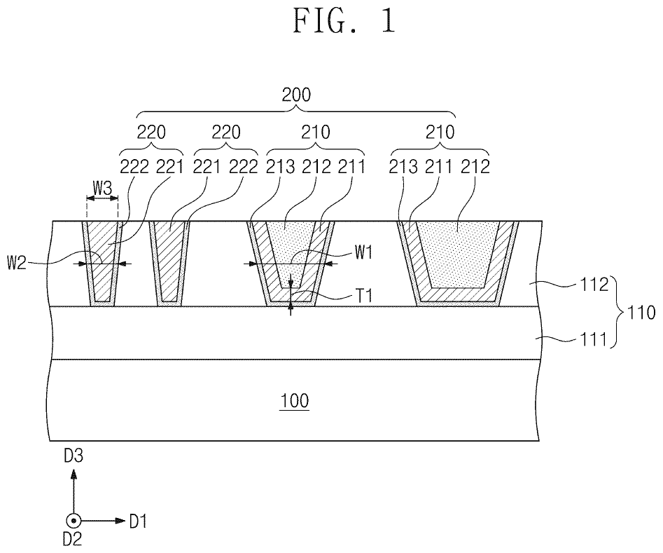

FIG. 1 is a sectional view illustrating a semiconductor device according to an example embodiment of the inventive concepts.

Referring to FIG. 1, a semiconductor device may include a substrate 100. In an example embodiment, the substrate 100 may be a semiconductor substrate. As an example, the substrate 100 may be formed of or include at least one of silicon (Si), germanium (Ge), silicon-germanium (SiGe), gallium phosphide (GaP), or gallium arsenide (GaAs), but example embodiments are not limited thereto. In an example embodiment, the substrate 100 may be a silicon-on-insulator (SOI) substrate or a germanium-on-insulator (GOI) substrate. The substrate 100 may be a plate-shaped element which is extended in a first direction D1 and a second direction D2. The first and second directions D1 and D2 may not be parallel to each other. As an example, the first and second directions D1 and D2 may be horizontal directions that are orthogonal to each other.

An insulating structure 110 may be provided on the substrate 100. The insulating structure 110 may include a first insulating layer 111 and a second insulating layer 112 on the first insulating layer 111. Each of the first and second insulating layers 111 and 112 may be formed of or include an insulating material. In an example embodiment, the first and second insulating layers 111 and 112 may be formed of or include different insulating materials. As an example, the first insulating layer 111 may be formed of or include nitride, and the second insulating layer 112 may be formed of or include oxide. In an example embodiment, the first and second insulating layers 111 and 112 may be formed of or include the same or substantially the same insulating material, and the first and second insulating layers 111 and 112 may form a single object, in which any interface is not formed. In an example embodiment, each of the first and second insulating layers 111 and 112 may be a multi-layered insulating layer including plurality of insulating layers.

The insulating structure 110 may cover a semiconductor element provided on the substrate 100. The semiconductor element may include, for example, a transistor, a capacitor, a resistor, a contact plug, and an interconnection line. In an example embodiment, the semiconductor element may be a memory element, a logic element, or an image sensor element.

Conductive structures 200 may be provided in the insulating structure 110. The conductive structures 200 may be provided on the first insulating layer 111. Each of the conductive structures 200 may have side and bottom surfaces that are in contact with the insulating structure 110. The side surface of each of the conductive structures 200 may be in contact with the second insulating layer 112, and the bottom surface may be in contact with the first insulating layer 111. The conductive structures 200 may be provided to penetrate the second insulating layer 112 in a third direction D3. The third direction D3 may not be parallel to the first and second directions D1 and D2. As an example, the third direction D3 may be a vertical direction that is orthogonal to the first and second directions D1 and D2.

The conductive structures 200 may include first conductive structures 210 and second conductive structures 220. The first and second conductive structures 210 and 220 may be disposed at the same or substantially the same level. A top surface of the first conductive structure 210 may be coplanar or substantially coplanar with a top surface of the second conductive structure 220. A width of the first conductive structure 210 may be larger than a width of the second conductive structure 220. As an example, a width W1 of the first conductive structure 210 in the first direction D1 may be larger than a width W2 of the second conductive structure 220 in the first direction D1. The conductive structures 200 may be electrically connected to a semiconductor element that is disposed on the substrate 100. In an example embodiment, the conductive structure 200 may be a conductive line that is extended in the second direction D2. In an example embodiment, the conductive structure 200 may be a conductive contact that is enclosed by the second insulating layer 112 of the insulating structure 110.

The first conductive structure 210 may include a first conductive layer 211, a second conductive layer 212, and a barrier layer 213. The second conductive layer 212 of the first conductive structure 210 may be provided in the first conductive layer 211 of the first conductive structure 210. The second conductive layer 212 of the first conductive structure 210 may be provided on the first conductive layer 211 of the first conductive structure 210. The first conductive layer 211 of the first conductive structure 210 may be in contact with side and bottom surfaces of the second conductive layer 212 of the first conductive structure 210. The first conductive layer 211 of the first conductive structure 210 may be provided in the barrier layer 213 of the first conductive structure 210. The first conductive layer 211 of the first conductive structure 210 may be provided on the barrier layer 213 of the first conductive structure 210. The barrier layer 213 of the first conductive structure 210 may be in contact with side and bottom surfaces of the first conductive layer 211 of the first conductive structure 210.

The second conductive structure 220 may include a conductive layer 221 and a barrier layer 222. The first conductive layer 221 of the second conductive structure 220 may be provided in the barrier layer 222 of the second conductive structure 220. The conductive layer 221 of the second conductive structure 220 may be provided on the barrier layer 222 of the second conductive structure 220. The barrier layer 222 of the second conductive structure 220 may be in contact with side and bottom surfaces of the conductive layer 221 of the second conductive structure 220.

The barrier layer 213 of the first conductive structure 210 and the barrier layer 222 of the second conductive structure 220 may be formed of or include at least one of conductive materials. As an example, the barrier layer 213 of the first conductive structure 210 and the barrier layer 222 of the second conductive structure 220 may be formed of or include TiN.

Twice a thickness of the first conductive layer 211 of the first conductive structure 210 may be larger than the largest width of the conductive layer 221 of the second conductive structure 220. As an example, twice a thickness T1 of the first conductive layer 211 of the first conductive structure 210 in the third direction D3 may be larger than the largest width W3 of the conductive layer 221 of the second conductive structure 220 in the first direction D1.

A mean size of grains in the second conductive layer 212 of the first conductive structure 210 may be different from a mean size of grains in the first conductive layer 211 of the first conductive structure 210 and a mean size of grains in the conductive layer 221 of the second conductive structure 220.

In an example embodiment, the mean size of grains in the second conductive layer 212 of the first conductive structure 210 may be larger than the mean size of grains in the first conductive layer 211 of the first conductive structure 210 and the mean size of grains in the conductive layer 221 of the second conductive structure 220.

In an example embodiment, the mean size of grains in the second conductive layer 212 of the first conductive structure 210 may be smaller than the mean size of grains in the first conductive layer 211 of the first conductive structure 210 and the mean size of grains in the conductive layer 221 of the second conductive structure 220.

The first conductive layer 211 of the first conductive structure 210 and the conductive layer 221 of the second conductive structure 220 may contain the same or substantially the same conductive material (e.g., a first conductive material) and the same or substantially the same nonmetal element (e.g., a first nonmetal element). In an example embodiment, the first conductive material may be at least one of W, Al, Cu, Mo, Co, TiN, TaN, WN, WCN, or TiSiN, and the first nonmetal element may be one of F, Cl, Br, C, O, or H, but example embodiments are not limited thereto.

In an example embodiment, the second conductive layer 212 of the first conductive structure 210 may include the first conductive material and the first nonmetal element, like the first conductive layer 211 of the first conductive structure 210 and the conductive layer 221 of the second conductive structure 220. A concentration of the first nonmetal element in the second conductive layer 212 of the first conductive structure 210 may be higher than a concentration of the first nonmetal element in the first conductive layer 211 of the first conductive structure 210 and a concentration of the first nonmetal element in the conductive layer 221 of the second conductive structure 220. As an example, a concentration of fluorine (F) in the second conductive layer 212 of the first conductive structure 210 may be about 10²⁰ atoms/cm³, and a concentration of the fluorine in the first conductive layer 211 of the first conductive structure 210 and a concentration of the fluorine in the conductive layer 221 of the second conductive structure 220 may be about 5×10¹⁹ atoms/cm³. Due to a difference in the concentration of the first nonmetal element, an etch rate of the second conductive layer 212 of the first conductive structure 210 (e.g., in a process of etching the first conductive material and by an etchant material used in the etching process) may be higher than an etch rate of the first conductive layer 211 of the first conductive structure 210 and an etch rate of the conductive layer 221 of the second conductive structure 220.

In an example embodiment, the concentration of the first nonmetal element in the first conductive layer 211 of the first conductive structure 210 may be equal to the concentration of the first nonmetal element in the conductive layer 221 of the second conductive structure 220.

In an example embodiment, the second conductive layer 212 of the first conductive structure 210 may contain a second nonmetal element different from the first nonmetal element. As an example, the second nonmetal element may be one element, which is chosen from F, Cl, Br, C, O, or H to be different from the first nonmetal element. In an embodiment, the second conductive layer 212 of the first conductive structure 210 may contain a second conductive material different from the first conductive material. As an example, the second conductive material may be at least one of W, Al, Cu, Mo, Co, TiN, TaN, WN, WCN, or TiSiN but may be chosen to be different from the first conductive material.

In an example embodiment, the second conductive layer 212 of the first conductive structure 210 may further contain nitrogen (N). In some example embodiments, a concentration of the nitrogen in the second conductive layer 212 of the first conductive structure 210 may be higher than a concentration of the nitrogen in the first conductive layer 211 of the first conductive structure 210 and a concentration of the nitrogen in the conductive layer 221 of the second conductive structure 220.

In an example embodiment, the first conductive layer 211 of the first conductive structure 210 and the conductive layer 221 of the second conductive structure 220 may be formed together by an atomic layer deposition (ALD) process, and the second conductive layer 212 of the first conductive structure 210 may be formed by a chemical vapor deposition (CVD) process.

In the semiconductor device according to an example embodiment of the inventive concepts, since the first conductive layer 211 of the first conductive structure 210 and the conductive layer 221 of the second conductive structure 220 have a relatively low concentration of the nonmetal element, it may be possible to reduce resistivity of the conductive structures 200 and to reduce a stress in the conductive structures 200 (e.g., caused by chemically-induced damage (CID)) and an amount of crack in the conductive structures 200.

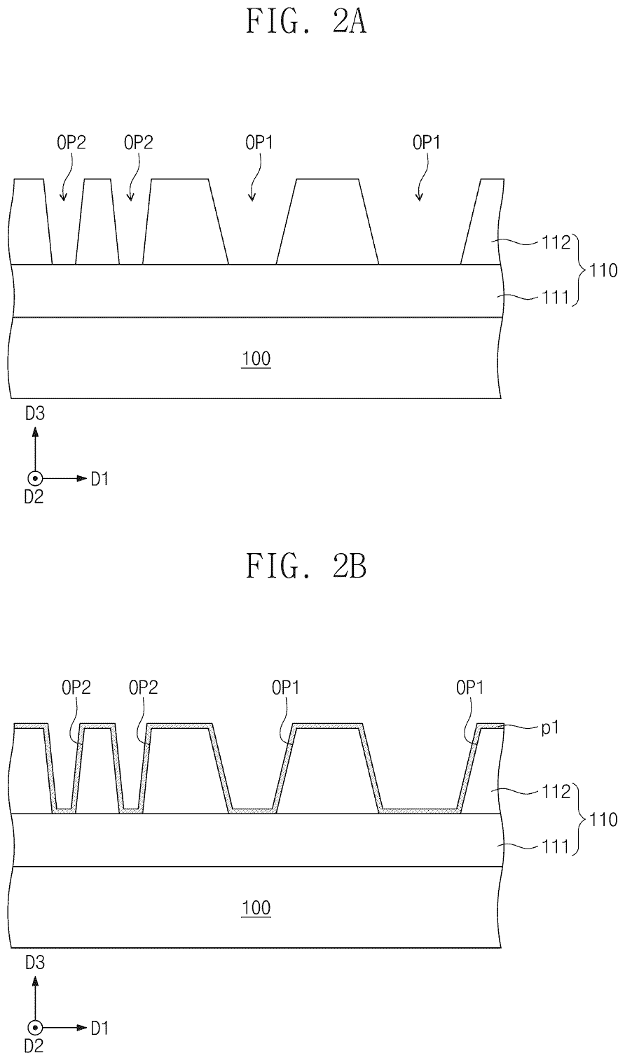

FIGS. 2A, 2B, 2C, and 2D are sectional views illustrating a method of fabricating the semiconductor device of FIG. 1.

Referring to FIG. 2A, the insulating structure 110 may be formed on the substrate 100. The second insulating layer 112 of the insulating structure 110 may be patterned to form first openings OP1 and second openings OP2. A width of the first opening OP1 may be larger than a width of the second opening OP2. As an example, a width of the first opening OP1 in the first direction D1 may be larger than a width of the second opening OP2 in the first direction D1. The first and second openings OP1 and OP2 may be formed to expose the first insulating layer 111 of the insulating structure 110.

Referring to FIG. 2B, a preliminary barrier layer p1 may be formed on the insulating structure 110. The preliminary barrier layer p1 may be formed to partially fill each of the first and second openings OP1 and OP2. A portion of the first opening OP1 may be filled with the preliminary barrier layer p1, and a portion of the second opening OP2 may be filled with the preliminary barrier layer p1. The first opening OP1 may include an empty space, which is not filled with the preliminary barrier layer p1. The second opening OP2 may include an empty space, which is not filled with the preliminary barrier layer p1.

In an example embodiment, the preliminary barrier layer p1 may be formed by an ALD or CVD process. The preliminary barrier layer p1 may be formed of or include at least one of conductive materials. As an example, the preliminary barrier layer p1 may be formed of or include TiN.

Referring to FIG. 2C, a first preliminary conductive layer p2 may be formed on the first preliminary barrier layer p1. The first preliminary conductive layer p2 may be formed to partially fill the first opening OP1 and to completely fill the second opening OP2. A portion of the first opening OP1 may be filled with the preliminary barrier layer p1 and the first preliminary conductive layer p2, and the entire portion of the second opening OP2 may be filled with the preliminary barrier layer p1 and the first preliminary conductive layer p2. The first opening OP1 may include an empty space, which is not filled with the preliminary barrier layer p1 and the first preliminary conductive layer p2. The second opening OP2 may include an empty space, which is not filled with the preliminary barrier layer p1 and the first preliminary conductive layer p2.

The first preliminary conductive layer p2 may be formed by an ALD process. The first preliminary conductive layer p2 may contain a first conductive material and a first nonmetal element. In an example embodiment, the first conductive material may be at least one of W, Al, Cu, Mo, Co, TiN, TaN, WN, WCN, or TiSiN, and the first nonmetal element may be one of F, Cl, Br, C, O, or H, but example embodiments are not limited thereto.

In an example embodiment, the first nonmetal element may be a ligand, which is separated from a precursor in a process of depositing a metal element included in the first conductive material. Since the first preliminary conductive layer p2 is formed by the ALD process, in which a step of purging the ligand separated from the precursor is repeated, a concentration of the first nonmetal element, which is included in the first preliminary conductive layer p2, may be relatively low.

Referring to FIG. 2D, a second preliminary conductive layer p3 may be formed on the first preliminary conductive layer p2. The second preliminary conductive layer p3 may be formed to completely fill the first opening OP1. The entire portion of the first opening OP1 may be filled with the preliminary barrier layer p1, the first preliminary conductive layer p2, and the second preliminary conductive layer p3. The first opening OP1 may not include an empty space, which is not filled with the preliminary barrier layer p1, the first preliminary conductive layer p2, and the second preliminary conductive layer p3.

The second preliminary conductive layer p3 may be formed by a CVD process. In an example embodiment, the second preliminary conductive layer p3 may include the first conductive material and the first nonmetal element, like the first preliminary conductive layer p2. Since the second preliminary conductive layer p3 is formed by the CVD process, in which the step of purging the ligand separated from the precursor is omitted, a concentration of the first nonmetal element, which is included in the second preliminary conductive layer p3, may be relatively high.

In an example embodiment, the second preliminary conductive layer p3 may contain a second conductive material different from the first conductive material. In an example embodiment, the second preliminary conductive layer p3 may contain a second nonmetal element different from the first nonmetal element.

Referring to FIG. 1, an upper portion of the preliminary barrier layer p1, an upper portion of the first preliminary conductive layer p2, and an upper portion of the second preliminary conductive layer p3 may be removed. In an example embodiment, the upper portion of the preliminary barrier layer p1, the upper portion of the first preliminary conductive layer p2, and the upper portion of the second preliminary conductive layer p3 may be removed by a chemical-mechanical polishing (CMP) process. As a result of the removal of the upper portion of the preliminary barrier layer p1, the upper portion of the first preliminary conductive layer p2, and the upper portion of the second preliminary conductive layer p3, the first and second conductive structures 210 and 220 may be formed.

The barrier layers 213 and 222 of the first and second conductive structures 210 and 220 may be formed by removing the upper portion of the preliminary barrier layer p1. The preliminary barrier layer p1 may be divided into the barrier layers 213 and 222 of the first and second conductive structures 210 and 220. The first conductive layers 211 of the first conductive structures 210 and the conductive layers 221 of the second conductive structures 220 may be formed by removing the upper portion of the first preliminary conductive layer p2. The first preliminary conductive layer p2 may be divided into the first conductive layers 211 of the first conductive structures 210 and the conductive layers 221 of the second conductive structures 220. The second conductive layers 212 of the first conductive structures 210 may be formed by removing the upper portion of the second preliminary conductive layer p3. The second preliminary conductive layer p3 may be divided into the second conductive layers 212 of the first conductive structures 210.

In a method of fabricating a semiconductor device according to an example embodiment of the inventive concepts, since the first preliminary conductive layer p2 is formed by the ALD process, it may be possible to prevent or suppress a seam from being formed in the second opening OP2 having a relatively small width.

In the method of fabricating a semiconductor device according to an example embodiment of the inventive concepts, since the first preliminary conductive layer p2 is formed by the ALD process, it may be possible to improve roughness and uniformity of a top surface of the second preliminary conductive layer p3 and to reduce technical difficulties in a subsequent CMP process.

In the method of fabricating a semiconductor device according to an example embodiment of the inventive concepts, since the second preliminary conductive layer p3 is formed by the CVD process, it may be possible to fill the first opening OP1 having a relatively large width more effectively.

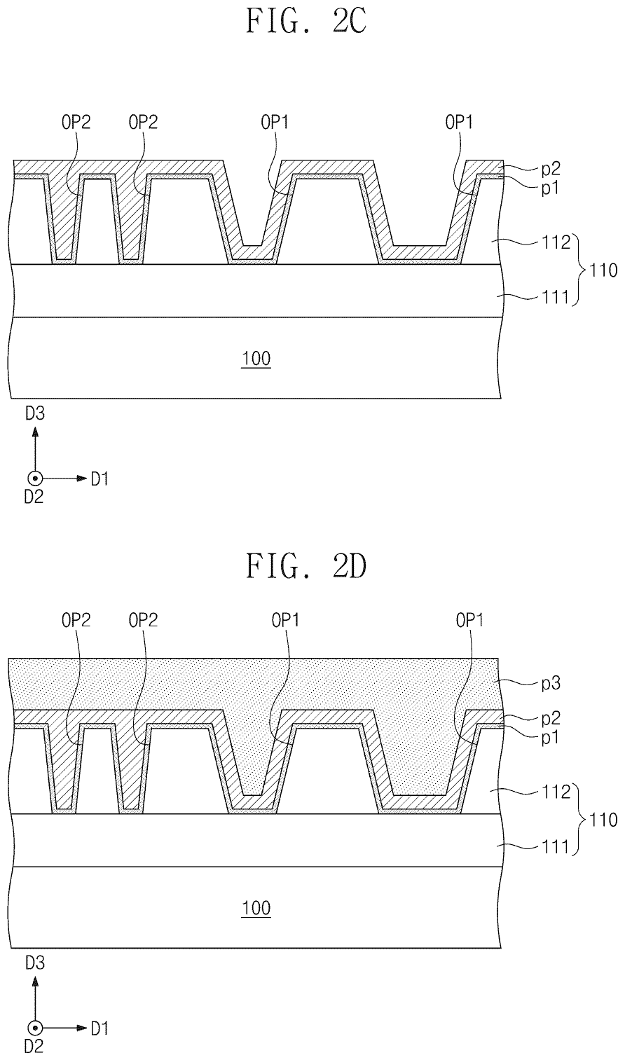

FIG. 3 is a sectional view illustrating a semiconductor device according to an example embodiment of the inventive concepts.

Referring to FIG. 3, a semiconductor device may include a substrate 100a and an insulating structure 110a on the substrate 100a. The insulating structure 110a may include a first insulating layer 111a on the substrate 100a and a second insulating layer 112a on the first insulating layer 111a.

Conductive structures 200a may be provided in the second insulating layer 112a of the insulating structure 110a. The conductive structures 200a may include first conductive structures 210a and second conductive structures 220a. A width of the first conductive structure 210a may be larger than a width of the second conductive structure 220a.

The first conductive structure 210a may include a first conductive layer 211a and a second conductive layer 212a in the first conductive layer 211a. The second conductive structure 220a may include a conductive layer 221a. The second conductive structure 220a may be composed of one conductive layer 221a. The first conductive layer 211a of the first conductive structure 210a may have side and bottom surfaces, which are in contact with the insulating structure 110a. The conductive layer 221a of the second conductive structure 220a may have side and bottom surfaces, which are in contact with the insulating structure 110a. Twice the thickness of the first conductive layer 211a of the first conductive structure 210a may be larger than the largest width of the conductive layer 221a of the second conductive structure 220a.

A mean size of grains in the second conductive layer 212a of the first conductive structure 210a may be different from a mean size of grains in the first conductive layer 211a of the first conductive structure 210a and a mean size of grains in the conductive layer 221a of the second conductive structure 220a.

In an example embodiment, a mean size of grains in the second conductive layer 212a of the first conductive structure 210a may be larger than a mean size of grains in the first conductive layer 211a of the first conductive structure 210a and a mean size of grains in the conductive layer 221a of the second conductive structure 220a.

In an example embodiment, a mean size of grains in the second conductive layer 212a of the first conductive structure 210a may be smaller than a mean size of grains in the first conductive layer 211a of the first conductive structure 210a and a mean size of grains in the conductive layer 221a of the second conductive structure 220a.

The first conductive layer 211a of the first conductive structure 210a and the conductive layer 221a of the second conductive structure 220a may contain the same or substantially the same metal element and the same or substantially the same nonmetal element (e.g., a first nonmetal element). As an example, the metal element may be molybdenum (Mo) or tungsten (W), and the first nonmetal element may be one of F, Cl, Br, C, O, or H, but example embodiments are not limited thereto.

The second conductive layer 212a of the first conductive structure 210a may be formed of or include at least one of conductive materials. As an example, the second conductive layer 212a of the first conductive structure 210a may be formed of or include at least one of W, Al, Cu, Mo, Co, TiN, TaN, WN, WCN, or TiSiN, but example embodiments are not limited thereto.

In an example embodiment, the second conductive layer 212a of the first conductive structure 210a may contain the same nonmetal element (e.g., the first nonmetal element) as the first conductive layer 211a of the first conductive structure 210a and the conductive layer 221a of the second conductive structure 220a. A concentration of the first nonmetal element in the second conductive layer 212a of the first conductive structure 210a may be higher than a concentration of the first nonmetal element in the first conductive layer 211a of the first conductive structure 210a and the conductive layer 221a of the second conductive structure 220a.

In an example embodiment, the second conductive layer 212a of the first conductive structure 210a may contain a nonmetal element (e.g., a second nonmetal element) different from the first nonmetal element.

In the semiconductor device according to an example embodiment of the inventive concepts, since the conductive structures 200a does not include a barrier layer, the conductive structures 200a may have relatively low resistivity.

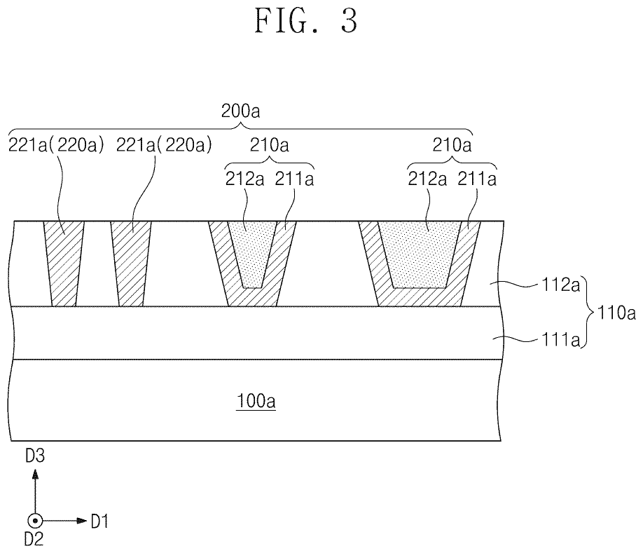

FIGS. 4A and 4B are sectional views illustrating a method of fabricating the semiconductor device of FIG. 3.

Referring to FIG. 4A, the insulating structure 110a including the first insulating layer 111a and the second insulating layer 112a may be formed on the substrate 100a, and first openings OP1a and second openings OP2a may be formed in the insulating structure 110a. The first opening OP1a may be formed to have a width larger than the second opening OP2a.

A first preliminary conductive layer p1a may be formed. The first preliminary conductive layer p1a may be formed to partially fill the first opening OP1a and to completely fill the second opening OP2a. The first preliminary conductive layer p1a may be formed by an ALD process.

Referring to FIG. 4B, a second preliminary conductive layer p2a may be formed on the first preliminary conductive layer p1a. The second preliminary conductive layer p2a may be formed to completely fill the first opening OP1a. The second preliminary conductive layer p2a may be formed by a CVD process.

Referring back to FIG. 3, the conductive structures 200a may be formed by removing an upper portion of the first preliminary conductive layer p1a and an upper portion of the second preliminary conductive layer p2a.

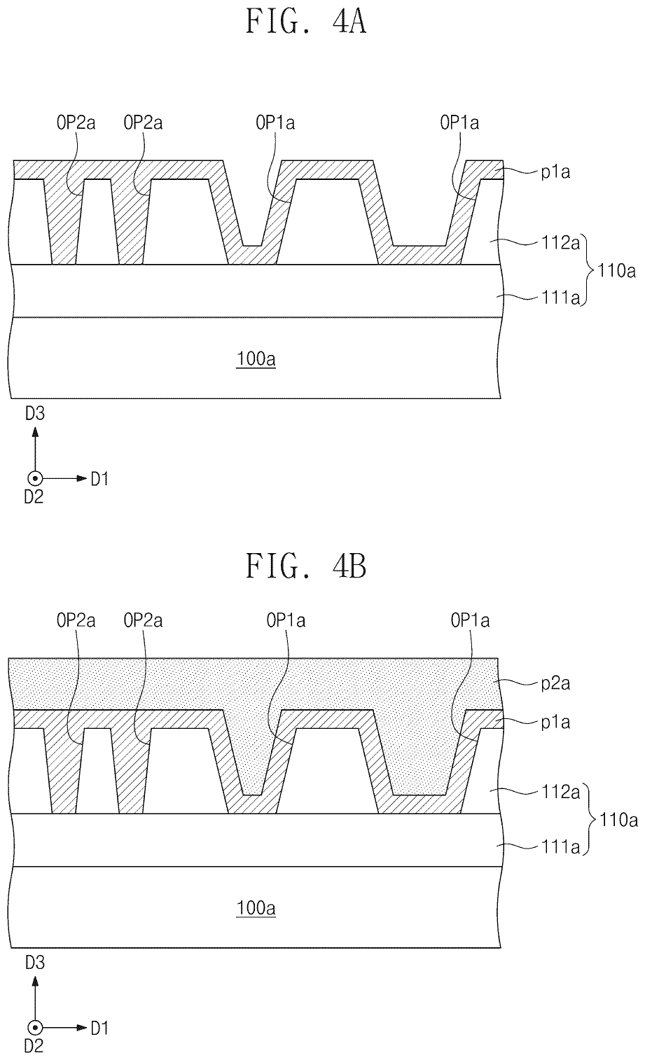

FIG. 5 is a sectional view illustrating a semiconductor device according to an example embodiment of the inventive concepts.

Referring to FIG. 5, a semiconductor device may include a substrate 100b and an insulating structure 110b on the substrate 100b. The insulating structure 110b may include a first insulating layer 111b on the substrate 100b and a second insulating layer 112b on the first insulating layer 111b.

Conductive structures 200b may be provided in the second insulating layer 112b of the insulating structure 110b. The conductive structures 200b may include first conductive structures 210b and second conductive structures 220b. A width of the first conductive structure 210b may be larger than a width of the second conductive structure 220b.

The first conductive structure 210b may include a first conductive layer 211b, a second conductive layer 212b, and a third conductive layer 214b. The second conductive layer 212b of the first conductive structure 210b may be provided in the first conductive layer 211b of the first conductive structure 210b, and the first and second conductive layers 211b and 212b of the first conductive structure 210b may be provided in the third conductive layer 214b of the first conductive structure 210b. The third conductive layer 214b of the first conductive structure 210b may have side and bottom surfaces, which are in contact with the insulating structure 110b.

The second conductive structure 220b may include a first conductive layer 221b and a second conductive layer 223b. The first conductive layer 221b of the second conductive structure 220b may be provided in the second conductive layer 223b of the second conductive structure 220b. The second conductive layer 223b of the second conductive structure 220b may have side and bottom surfaces, which are in contact with the insulating structure 110b. Twice the thickness of the first conductive layer 211b of the first conductive structure 210b may be larger than the largest width of the first conductive layer 221b of the second conductive structure 220b.

A mean size of grains in the second conductive layer 212b of the first conductive structure 210b may be different from a mean size of grains in each of the first and third conductive layers 211b and 214b of the first conductive structure 210b and a mean size of grains in each of the first and second conductive layers 221b and 223b of the second conductive structure 220b.

In an example embodiment, the mean size of grains in the second conductive layer 212b of the first conductive structure 210b may be larger than the mean size of grains in each of the first and third conductive layers 211b and 214b of the first conductive structure 210b and the mean size of grains in each of the first and second conductive layers 221b and 223b of the second conductive structure 220b.

In an example embodiment, the mean size of grains in the second conductive layer 212b of the first conductive structure 210b may be smaller than the mean size of grains in each of the first and third conductive layers 211b and 214b of the first conductive structure 210b and the mean size of grains in each of the first and second conductive layers 221b and 223b of the second conductive structure 220b.

The second conductive layer 212b of the first conductive structure 210b may be formed by a CVD process, and the first and third conductive layers 211b and 214b of the first conductive structure 210b and the first and second conductive layers 221b and 223b of the second conductive structure 220b may be formed by an ALD process.

The third conductive layer 214b of the first conductive structure 210b and the second conductive layer 223b of the second conductive structure 220b may be formed of or include the same or substantially the same metal element (e.g., the first metal element). In an example embodiment, the first metal element may be molybdenum (Mo).

The first conductive layer 211b of the first conductive structure 210b and the first conductive layer 221b of the second conductive structure 220b may be formed of or include a metal element (e.g., a second metal element) different from the first metal element. In an embodiment, the second metal element may be tungsten (W). The second conductive layer 212b of the first conductive structure 210b may include a conductive material, which is the same as or different from the second metal element.

The first to third conductive layers 211b, 212b, and 214b of the first conductive structure 210b and the first and second conductive layers 221b and 223b of the second conductive structure 220b may include the same nonmetal element or may include nonmetal elements different from each other. A concentration of the nonmetal element in the second conductive layer 212b of the first conductive structure 210b may be higher than a concentration of the nonmetal element in the first and third conductive layers 211b and 214b of the first conductive structure 210b and the first and second conductive layers 221b and 223b of the second conductive structure 220b.

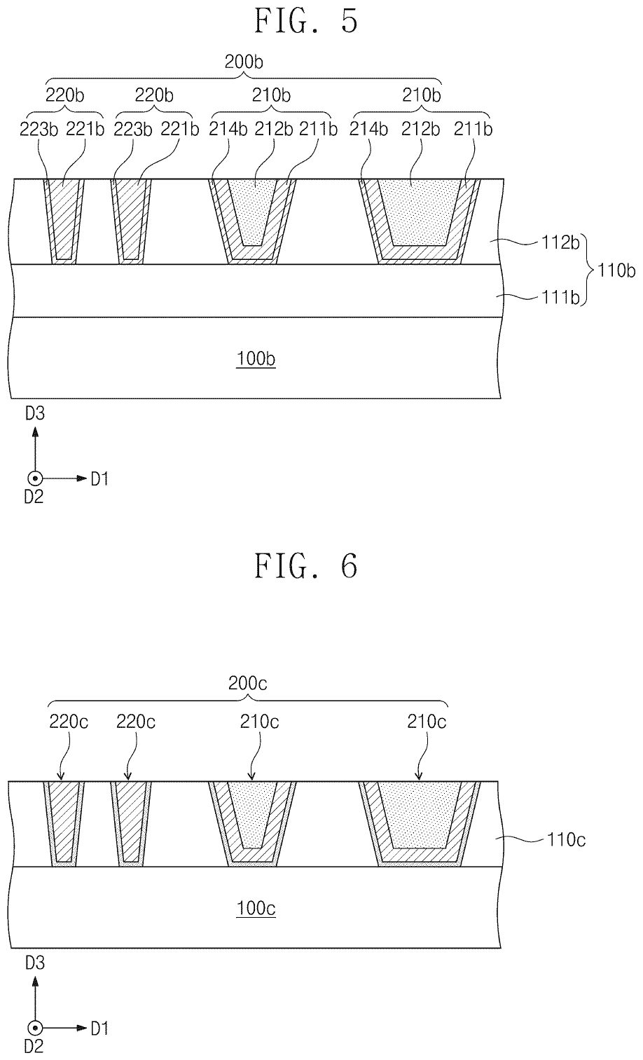

FIG. 6 is a sectional view illustrating a semiconductor device according to an example embodiment of the inventive concepts.

Referring to FIG. 6, a semiconductor device may include a substrate 100c and an insulating structure 110c on the substrate 100c.

Conductive structures 200c may be provided in the insulating structure 110c. The conductive structures 200c may include first conductive structures 210c and second conductive structures 220c. A width of the first conductive structure 210c may be larger than a width of the second conductive structure 220c. The conductive structures 200c may be provided to penetrate the insulating structure 110c and to be in direct contact with the substrate 100c. In an example embodiment, at least a portion of each of the conductive structures 200c may be provided in the substrate 100c.

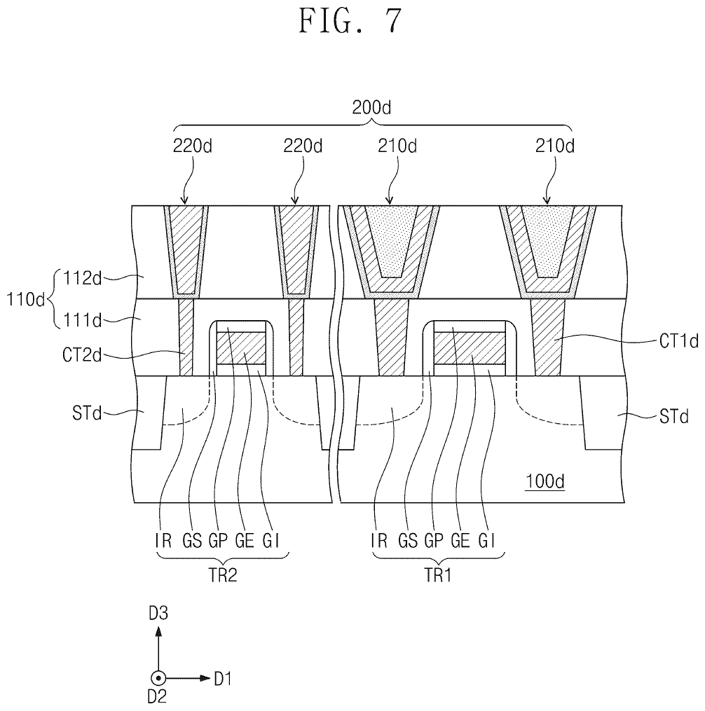

FIG. 7 is a sectional view illustrating a semiconductor device according to an example embodiment of the inventive concepts.

Referring to FIG. 7, a semiconductor device may include a substrate 100d. An insulating structure 110d may be provided on the substrate 100d. The insulating structure 110d may include a first insulating layer 111d, which is provided to cover the substrate 100d, and a second insulating layer 112d, which is provided on the first insulating layer 111d.

A first transistor TR1 and a second transistor TR2 may be provided on the substrate 100d. In an example embodiment, each of the first and second transistors TR1 and TR2 may be one of cell or peripheral transistors constituting a memory device, a logic device, or an image sensor device. The first and second transistors TR1 and TR2 may be covered with the first insulating layer 111d of the insulating structure 110d. The first and second transistors TR1 and TR2 may be different from each other in terms of size or function.

Each of the first and second transistors TR1 and TR2 may include impurity regions IR, a channel disposed between the impurity regions IR and a gate structure on the channel. The gate structure may include gate spacers GS, a gate insulating layer GI, a gate electrode GE, and a gate capping layer GP, and here, the gate insulating layer GI, the gate electrode GE, and the gate capping layer GP may be disposed between the gate spacers GS. The impurity regions IR may be formed by injecting impurities into the substrate 100d. The gate spacers GS, the gate insulating layer GI, and the gate capping layer GP may be formed of or include at least one of insulating materials. The gate electrode GE may be formed of or include at least one of conductive materials. However, the inventive concepts are not limited to the illustrated structure of the first and second transistors TR1 and TR2. In an example embodiment, the transistor may include a buried gate electrode. In an example embodiment, the transistor may include a vertical gate electrode. In an example embodiment, the transistor may be provided to have a gate-all-around structure.

Device isolation layers STd may be provided in the substrate 100d. The first and second transistors TR1 and TR2 may be provided between the device isolation layers STd. The device isolation layers STd may be formed of or include at least one of insulating materials.

First contacts CT1d and second contacts CT2d may be provided in the first insulating layer 111d of the insulating structure 110d. The first contacts CT1d may be connected to the first transistor TR1, and the second contacts CT2d may be connected to the second transistor TR2. The first and second contacts CT1d and CT2d may be formed of or include at least one of conductive materials.

Conductive structures 200d may be provided in the second insulating layer 112d of the insulating structure 110d. The conductive structures 200d may include first conductive structures 210d and second conductive structures 220d. A width of the first conductive structure 210d may be larger than a width of the second conductive structure 220d.

The first conductive structure 210d may be electrically connected to the first transistor TR1 through the first contact CT1d. The second conductive structure 220d may be connected to the second transistor TR2 through the second contact CT2d.

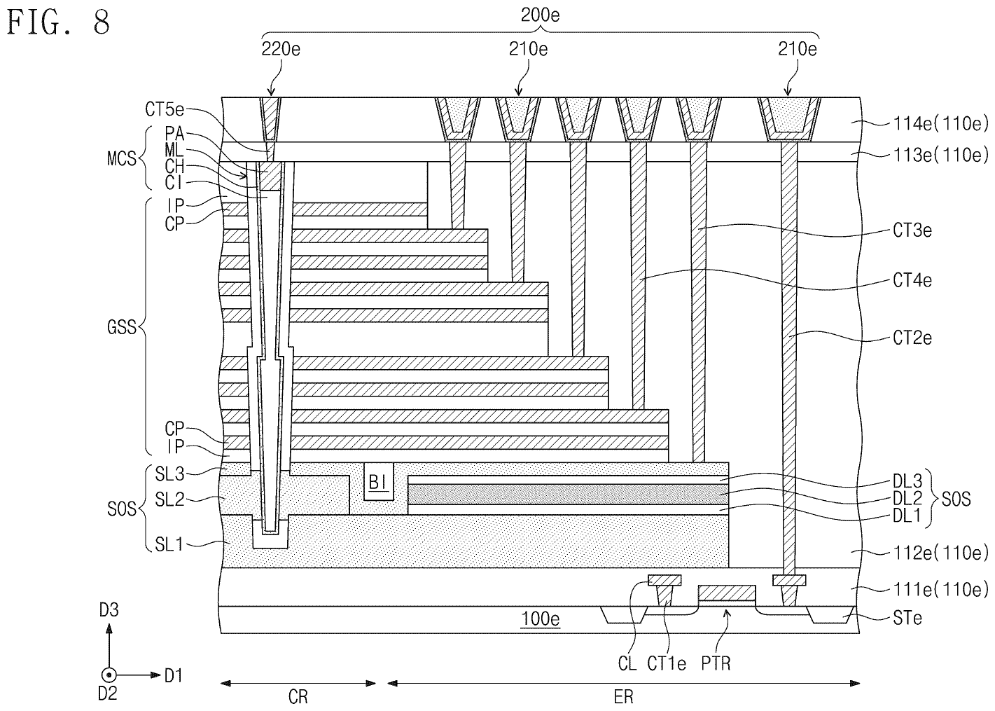

FIG. 8 is a sectional view illustrating a semiconductor device according to an example embodiment of the inventive concepts.

Referring to FIG. 8, a semiconductor device may include a cell region CR and an extension region ER. The cell region CR and the extension region ER may be two distinct regions that are differentiated from each other in a plan view defined in the first and second directions D1 and D2.

The semiconductor device may include a substrate 100e. An insulating structure 110e may be provided on the substrate 100e. The insulating structure 110e may include a first insulating layer 111e on the substrate 100e, a second insulating layer 112e on the first insulating layer 111e, a third insulating layer 113e on the second insulating layer 112e, and a fourth insulating layer 114e on the third insulating layer 113e.

A peripheral transistor PTR may be provided on the substrate 100e. The peripheral transistor PTR may include impurity regions, a channel disposed between the impurity regions and a gate structure on the channel Device isolation layers STe may be provided in the substrate 100e. The peripheral transistor PTR may be provided between the device isolation layers STe.

First contacts CT1e and interconnection lines CL may be provided in the first insulating layer 111e. The first contacts CT1e and the interconnection lines CL may be connected to the peripheral transistor PTR.

A source structure SOS may be provided on the first insulating layer 111e. The source structure SOS may include a first source layer SL1 on the first insulating layer 111e, a second source layer SL2 on the first source layer SL1, first to third dummy layers DL1, DL2, and DL3 on the first source layer SL1, and a third source layer SL3 on the second source layer SL2 and the first to third dummy layers DL1, DL2, and DL3.

The first to third source layers SL1, SL2, and SL3 may be formed of or include at least one of conductive materials. As an example, the first to third source layers SL1, SL2, and SL3 may be formed of or include poly silicon. The second source layer SL2 may be disposed in the cell region CR. The second source layer SL2 may be used as a common source line.

The first dummy layer DL1, the second dummy layer DL2, and the third dummy layer DL3 may be sequentially provided on the first source layer SL1 in the third direction D3. The first to third dummy layers DL1, DL2, and DL3 may be disposed in the extension region ER. The first to third dummy layers DL1, DL2, and DL3 may be disposed at the same or substantially the same level as the second source layer SL2. The first to third dummy layers DL1, DL2, and DL3 may be formed of or include at least one of insulating materials. In an example embodiment, the first and third dummy layers DL1 and DL3 may be formed of or include the same or substantially the same insulating material, and the second dummy layer DL2 may be formed of or include an insulating material different from the first and third dummy layers DL1 and DL3. As an example, the second dummy layer DL2 may be formed of or include silicon nitride, and the first and third dummy layers DL1 and DL3 may be formed of or include silicon oxide.

The third source layer SL3 may cover the second source layer SL2 and the first to third dummy layers DL1, DL2, and DL3. The third source layer SL3 may be extended from the cell region CR to the extension region ER.

In an embodiment, the source structure SOS may further include an insulating gapfill layer BI on the third source layer SL3. The insulating gapfill layer BI may be provided between the cell region CR and the extension region ER. The insulating gapfill layer BI may be provided between the second source layer SL2 and the first to third dummy layers DL1, DL2, and DL3. The second source layer SL2 may be spaced apart from the first to third dummy layers DL1, DL2, and DL3 in the first direction D1, and here, the insulating gapfill layer BI and a portion of the third source layer SL3 enclosing the insulating gapfill layer BI may be interposed between the second source layer SL2 and the first to third dummy layers DL1, DL2, and DL3. The insulating gapfill layer BI may be formed of or include at least one of insulating materials.

A gate stack GSS may be provided on the source structure SOS. The gate stack GSS may include insulating patterns IP and conductive patterns CP, which are alternately stacked in the third direction D3. The insulating patterns IP may be formed of or include at least one of insulating materials. As an example, the insulating patterns IP may be formed of or include oxide. The conductive patterns CP may be formed of or include at least one of conductive materials. The gate stack GSS may have a stepwise structure in the extension region ER.

A memory channel structure MCS may be provided to extend in the third direction D3 and to penetrate the gate stack GSS. The memory channel structure MCS may be disposed in the cell region CR. The memory channel structure MCS may be enclosed by the insulating and conductive patterns IP and CP of the gate stack GSS. The lowermost portion of the memory channel structure MCS may be disposed in the first source layer SL1 of the source structure SOS.

The memory channel structure MCS may include a core insulating layer CI, a pad PA on the core insulating layer CI, a channel layer CH enclosing the core insulating layer CI and the pad PA, and a memory layer ML enclosing the channel layer CH. The core insulating layer CI may be formed of or include at least one of insulating materials. As an example, the core insulating layer CI may be formed of or include oxide. The pad PA may be formed of or include at least one of conductive materials. The channel layer CH may be electrically connected to the second source layer SL2 of the source structure SOS. The channel layer CH may be formed of or include at least one of conductive materials. As an example, the channel layer CH may be formed of or include poly silicon. The memory layer ML may include a tunnel insulating layer enclosing the channel layer CH, a charge storing layer enclosing the tunnel insulating layer, and a blocking layer enclosing the charge storing layer. The tunnel insulating layer may be formed of or include a material allowing for the tunnelling of electric charges. As an example, the tunnel insulating layer may be formed of or include silicon oxide. The charge storing layer may be formed of or include a material which can store electric charges. As an example, the charge storing layer may be formed of or include silicon nitride. The blocking layer may be formed of or include a material which can block electric charges from being moved. As an example, the blocking layer may be formed of or include silicon oxide.

The second insulating layer 112e may be provided to cover the stepwise structure of the gate stack GSS and the source structure SOS. The third insulating layer 113e may cover the gate stack GSS, the memory channel structure MCS, and the second insulating layer 112e.

A second contact CT2e, a third contact CT3e, a fourth contacts CT4e, and a fifth contact CT5e may be provided. The second contact CT2e may be provided to penetrate the second and third insulating layers 112e and 113e and may be connected to the conductive line CL. The third contact CT3e may be provided to penetrate the second and third insulating layers 112e and 113e and may be connected to the third source layer SL3 of the source structure SOS. Each of the fourth contacts CT4e may be provided to penetrate the second and third insulating layers 112e and 113e and may be connected to a corresponding one of the conductive patterns CP. The fifth contact CT5e may be provided to penetrate the third insulating layer 113e and may be connected to the pad PA.

The fourth insulating layer 114e may cover the third insulating layer 113e and the second to fifth contacts CT2e, CT3e, CT4e, and CT5e. Conductive structures 200e may be provided in the fourth insulating layer 114e. The conductive structures 200e may include first conductive structures 210e and second conductive structures 220e. A width of the first conductive structure 210e may be larger than a width of the second conductive structure 220e.

The first conductive structure 210e may be connected to the second contact CT2e, the third contact CT3e, or the fourth contact CT4e. The second conductive structure 220e may be connected to the fifth contact CT5e.

In a semiconductor device according to an example embodiment of the inventive concepts, it may be possible to provide conductive structures having a relatively low resistivity and a relatively small internal stress.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%)).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

While some example embodiments of the inventive concepts have been particularly shown and described, it will be understood by one of ordinary skill in the art that variations in form and detail may be made therein without departing from the scope of the inventive concepts.

1. A semiconductor device, comprising:
an insulating structure;
a first conductive structure in the insulating structure, the first conductive structure including a first conductive layer and a second conductive layer, wherein the second conductive layer is in the first conductive layer; and
a second conductive structure in the insulating structure, the second conductive structure including a first conductive layer of the second conductive structure,
wherein a width of the first conductive structure is larger than a width of the second conductive structure,
the first conductive layer of the first conductive structure, the second conductive layer of the first conductive structure, and the first conductive layer of the second conductive structure include a same nonmetal element,
a concentration of the nonmetal element in the second conductive layer of the first conductive structure is higher than a concentration of the nonmetal element in the first conductive layer of the first conductive structure, and
the concentration of the nonmetal element in the second conductive layer of the first conductive structure is higher than a concentration of the nonmetal element in the first conductive layer of the second conductive structure.

2. The semiconductor device of claim 1, wherein the nonmetal element is one of F, Cl, Br, O, H, or C.

3. The semiconductor device of claim 1, wherein
the first conductive layer of the first conductive structure and the first conductive layer of the second conductive structure comprise a same conductive material, and
the second conductive layer of the first conductive structure comprises a conductive material different from the first conductive layer of the first conductive structure and the first conductive layer of the second conductive structure.

4. The semiconductor device of claim 1, wherein the first conductive layer of the first conductive structure, the second conductive layer of the first conductive structure, and the first conductive layer of the second conductive structure comprise a same conductive material.

5. The semiconductor device of claim 1, wherein each of the first and second conductive structures further comprises a barrier layer.

6. The semiconductor device of claim 1, wherein a concentration of the nonmetal element in the first conductive layer of the first conductive structure is equal to a concentration of the nonmetal element in the first conductive layer of the second conductive structure.

7. The semiconductor device of claim 1, wherein
a mean size of grains in the second conductive layer of the first conductive structure is larger than a mean size of grains in the first conductive layer of the first conductive structure, and
the mean size of grains in the second conductive layer of the first conductive structure is larger than a mean size of grains in the first conductive layer of the second conductive structure.

8. The semiconductor device of claim 1, wherein
the first conductive layer of the first conductive structure has side and bottom surfaces in contact with the insulating structure, and
the first conductive layer of the second conductive structure has side and bottom surfaces in contact with the insulating structure.

9. The semiconductor device of claim 1, wherein
the first conductive structure further comprises a third conductive layer covering side and bottom surfaces of the first conductive layer of the first conductive structure,
the second conductive structure further comprises a second conductive layer of the second conductive structure, and the second conductive layer of the second conducive structure covers side and bottom surfaces of the first conductive layer of the second conductive structure,
the third conductive layer of the first conductive structure and the second conductive layer of the second conductive structure include the nonmetal element,
a concentration of the nonmetal element in the second conductive layer of the first conductive structure is higher than a concentration of the nonmetal element in the third conductive layer of the first conductive structure, and
the concentration of the nonmetal element in the second conductive layer of the first conductive structure is higher than a concentration of the nonmetal element in the second conductive layer of the second conductive structure.

10. The semiconductor device of claim 9, wherein
the third conductive layer of the first conductive structure and the second conductive layer of the second conductive structure each include a first metal element,
the first conductive layer of the first conductive structure and the first conductive layer of the second conductive structure each include a second metal element, and
the first metal element is different from the second metal element.

11. The semiconductor device of claim 1, wherein a top surface of the first conductive structure is coplanar with a top surface of the second conductive structure.

12. A semiconductor device, comprising:
an insulating structure;
a first conductive structure in the insulating structure, the first conductive structure including a first conductive layer and a second conductive layer, wherein the second conductive layer is in the first conductive layer; and
a second conductive structure in the insulating structure, the second conductive structure including a first conductive layer of the second conductive structure,
wherein a width of the first conductive structure is larger than a width of the second conductive structure,
a mean size of grains in the second conductive layer of the first conductive structure is larger than a mean size of grains in the first conductive layer of the first conductive structure, and
the mean size of grains in the second conductive layer of the first conductive structure is larger than a mean size of grains in the first conductive layer of the second conductive structure.

13. The semiconductor device of claim 12, wherein
the first conductive layer of the first conductive structure, the second conductive layer of the first conductive structure, and the first conductive layer of the second conductive structure include a same nonmetal element,
a concentration of the nonmetal element in the second conductive layer of the first conductive structure is higher than a concentration of the nonmetal element in the first conductive layer of the first conductive structure, and
the concentration of the nonmetal element in the second conductive layer of the first conductive structure is higher than a concentration of the nonmetal element in the first conductive layer of the second conductive structure.

14. The semiconductor device of claim 12, further comprising a substrate,
wherein the first conductive structure and the second conductive structure are directly connected to the substrate.

15. The semiconductor device of claim 12, wherein the first conductive layer of the first conductive structure, the second conductive layer of the first conductive structure, and the first conductive layer of the second conductive structure include tungsten (W) and fluorine (F).

16. The semiconductor device of claim 15, wherein
a concentration of the fluorine in the second conductive layer of the first conductive structure is higher than a concentration of the fluorine in the first conductive layer of the first conductive structure, and
the concentration of the fluorine in the second conductive layer of the first conductive structure is higher than a concentration of the fluorine in the first conductive layer of the second conductive structure.

17. The semiconductor device of claim 16, wherein
the first conductive structure further comprises a third conductive layer covering side and bottom surfaces of the first conductive layer of the first conductive structure,
the second conductive structure further comprises a second conductive layer of the second conductive structure, and the second conductive layer of the second conductive structure covers side and bottom surfaces of the first conductive layer of the second conductive structure, and
the third conductive layer of the first conductive structure and the second conductive layer of the second conductive structure include molybdenum (Mo).

18. The semiconductor device of claim 12, wherein
a concentration of nitrogen in the second conductive layer of the first conductive structure is higher than a concentration of nitrogen in the first conductive layer of the first conductive structure, and
the concentration of nitrogen in the second conductive layer of the first conductive structure is higher than a concentration of nitrogen in the first conductive layer of the second conductive structure.

19. A semiconductor device, comprising:
an insulating structure;
a first conductive structure in the insulating structure, the first conductive structure including a first conductive layer and a second conductive layer, wherein the second conductive layer is in the first conductive layer; and
a second conductive structure in the insulating structure, the second conductive structure including a conductive layer,
wherein a width of the first conductive structure is larger than a width of the second conductive structure,
the first conductive structure is at a same level as the second conductive structure,
the first conductive layer of the first conductive structure, the second conductive layer of the first conductive structure, and the conductive layer of the second conductive structure include a same nonmetal element,
a concentration of the nonmetal element in the second conductive layer of the first conductive structure is higher than a concentration of the nonmetal element in the first conductive layer of the first conductive structure,
the concentration of the nonmetal element in the second conductive layer of the first conductive structure is higher than a concentration of the nonmetal element in the conductive layer of the second conductive structure, and
the nonmetal element is one of F, Cl, Br, C, O, or H.

20. The semiconductor device of claim 19, wherein the first conductive layer of the first conductive structure, the second conductive layer of the first conductive structure, and the conductive layer of the second conductive structure further include at least one of W, Al, Cu, Mo, Co, TiN, TaN, WN, WCN, or TiSiN.

21. (canceled)
